(19) United States
(12) Patent Application Publication
(10) Pub. No.: US 2016/0111571 A1
(43) Pub. Date: Apr. 21, 2016

(54) PRIMED EDGE SEALING TAPE FOR PHOTOVOLTAIC MODULE

(71) Applicant: QUANEX IG SYSTEMS INC., Cambridge, OH (US)

(72) Inventors: Louis Anthony FERRI, Solon, OH (US); Lori Aruscavage POSTAK, University Heights, OH (US)

(21) Appl. No.: 14/410,327

(22) PCT Filed: Jun. 24, 2013
(86) PCT No.: PCT/US2013/047344

§ 371 Date: Dec. 22, 2014

Related U.S. Application Data
(60) Provisional application No. 61/663,388, filed on Jun. 22, 2012.

(51) Int. Cl. H01L 31/048

(52) U.S. Cl. CPC H01L 31/0481

(57) ABSTRACT

An edge sealing tape for photovoltaic modules includes a primer suitable for bonding the edge sealing tape to the top sheet of the module. In one exemplary configuration, the edge sealing tape is a polyisobutylene-based material such as butyl and carries a primer disposed between one side of the edge sealing tape and a release liner wherein the primer is configured to bond with a fluoropolymer-based top sheet such that the edge sealing tape cohesively fails after the primer bonds the tape to the top sheet.

### BACKGROUND OF THE DISCLOSURE

1. Technical Field

The disclosure generally relates to flexible low moisture vapor transmission rate (low MVTR) sealing tapes and, more particularly, to a desiccated flexible low MVTR sealing tape for sealing the edge of photovoltaic modules wherein one surface of the tape is primed for bonding to a fluoropolymer-based member. The disclosure also relates to a photovoltaic cell, module, or array that includes the primed tape and different methods for manufacturing and using the primed tape.

2. Background Information

A photovoltaic module generally includes two silicone layers, a bottom contact, and a top contact grid sealed between top and back substrates or sheets using a clear laminating adhesive such as EVA (ethylene vinyl acetate) or PVB (polyvinyl butyral). A low MVTR edge seal is used about the perimeter between the top and back substrates to seal the interior of the module against moisture and moisture vapor. Clear fluoropolymer films, such as those sold by Dupont or 3M, are used as the top layer of some photovoltaic modules. The fluoropolymer-based films protect the modules from damage and increase their useful life.

One type of low MVTR edge tape is a desiccated butyl sealing tape. Bonding a low MVTR desiccated butyl edge tape to a flexible fluoropolymer-based top sheet in a photovoltaic module can be problematic due to the top sheet chemical structure which is predominately fluoropolymer based. In order to achieve a good bond, which fails in a cohesive manner in a typical peel test to the fluoropolymer substrate, requires some type of primer to make the butyl tape bond to the substrate. Problems exist with primers in their application. Typically they can be solvent borne coatings with non-VOC compliant solvents making up a large portion of the system. Many users shy away from the solvent borne coatings for health and safety reasons. Another issue with the use of primers is the time that is required to allow the coating to dry can sometimes be excessive.

### SUMMARY OF THE DISCLOSURE

The disclosure provides an edge sealing tape for photovoltaic modules wherein one side of the edge sealing tape carries a primer suitable for bonding the edge sealing tape to the top sheet. In one exemplary configuration, the edge sealing tape is a polyisobutylene-based material such as butyl and carries a primer disposed between one side of the edge sealing tape and a release liner wherein the primer is configured to bond with a fluoropolymer-based top sheet such that the edge sealing tape cohesively fails after the primer bonds the tape to the top sheet.

The disclosure also provides a photovoltaic module that incorporates the primed tape described above.

The disclosure also provides a method for forming the edge sealing tape described above. The method generally includes the steps of casting the primer onto a release layer and then flashing off the solvent with heat. The resulting primer film assembly is slit to the desired width and wound for use. The primer film assembly is then fed through an extrusion process and a desiccated low MVTR pressure sensitive adhesive material is applied to the primer film assembly so that the primer and the desiccated low MVTR material are in intimate contact with one another to form a desiccated low MVTR pressure sensitive tape. The desiccated low MVTR material may be a polyisobutylene-based material such as butyl. This intimate contact occurs while the desiccated low MVTR material is at an elevated temperature during the extrusion process and, as such, there is excellent bonding between the desiccated low MVTR material and the primer.

The disclosure also provides a method for using the primed edge sealing tape with a top sheet and a bottom sheet to form a sealed photovoltaic unit. When the low MVTR pressure sensitive tape is removed from the release film, the primer is carried on an exterior side of the tape such that the primer may be placed in contact with the fluoropolymer top sheet to secure bonding between the tape and the top sheet.

The disclosure also provides an alternative method wherein the primer film is connected to the low MVTR adhesive material after the low MVTR material is connected to one of the substrates or sheets of the photovoltaic module.

### BRIEF DESCRIPTION OF THE DRAWINGS

FIG. 1 is a cross section of the edge sealing tape having a primer on one side with the release layer disposed on the primer.

FIG. 2 is a cross section of the edge of a photovoltaic unit showing the tape disposed between the top sheet and the bottom substrate.

FIG. 3 is a schematic drawing showing steps of creating the primer and release layer assembly.

FIG. 4 is a schematic drawing showing steps of forming the low MVTR desiccated tape.

FIG. 5 is a schematic drawing showing the steps of an alternative configuration wherein the low MVTR material is already connected to a substrate when the primer and release layer assembly are connected to the material.

The drawings are not to scale and are schematic. Similar reference numbers refer to similar structures through the specification.

### DETAILED DESCRIPTION OF THE DISCLOSURE

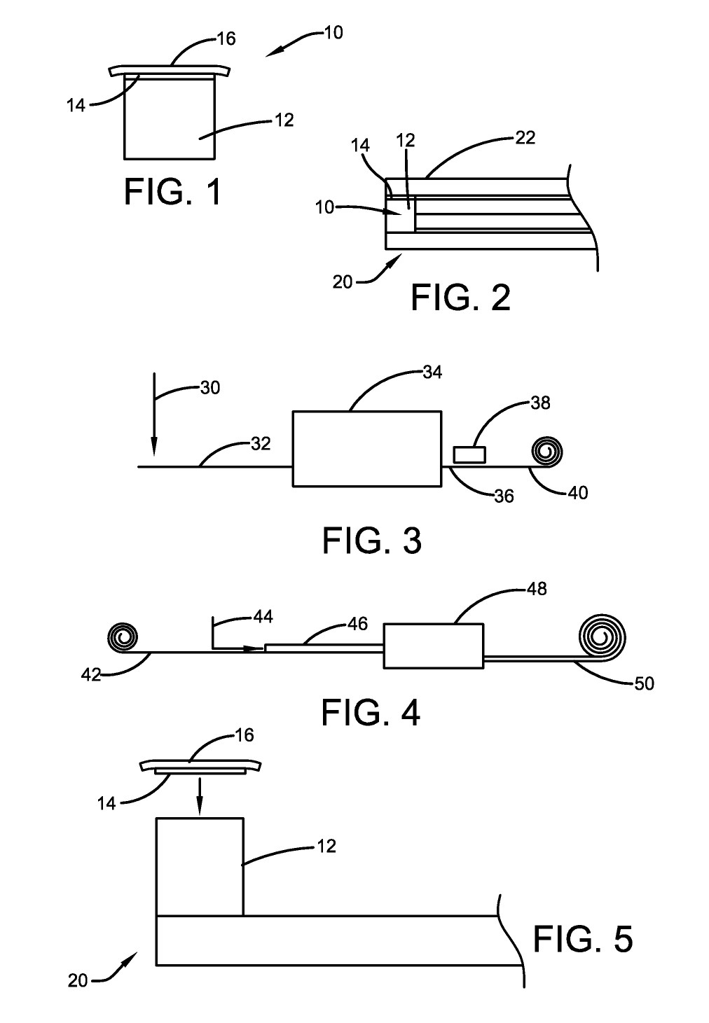

FIG. 1 depicts a low MVTR pressure sensitive edge sealing tape 10 useful for the manufacture of photovoltaic units. Tape 10 has a sealing body 12, a primer layer 14, and a release layer 16. Sealing body 12 may be a desiccated polyisobutylene-based material such as butyl. Primer layer 14 may be formed from a primer suitable for bonding with a fluoropolymer-based substrate such as, for example, Primer 94 sold by 3M. Other suitable primers may be used. Desiccant that may be carried by the polyisobutylene-based sealing body 12 include silica gel, zeolites such as molecular sieves, calcium oxide, calcium sulfate or magnesium sulfate.

Tape 10 of FIG. 1 is used to seal the perimeter edge of a photovoltaic unit 20 depicted in FIG. 2 wherein the top sheet 22 is fluoropolymer-based. Primer layer 14 is configured to bond to top sheet 22 such that sealing body 12 will fail before the bond between primer 14 and top sheet 22 fails.

As shown in FIGS. 3 and 4, tape 10 is formed by casting the liquid primer 30 onto a sheet 32 of release liner material and then flashing off the primer's solvent at location 34. The removal of the solvent is conducted in a controlled manner in a controlled location such as an oven 34 so that undesirable release of the solvent and human interaction with the solvent is minimized. The resulting primer film assembly 36 is slit with a slitter 38 to the desired width and wound for use on winder 40. As shown in FIG. 4, the primer and release layer assembly or primed release layer 42 is then fed through an extrusion process 44 and a desiccated low MVTR pressure sensitive adhesive material 46 is applied to the primer and film assembly so that the primer 14 and the desiccated low MVTR material 46 are in intimate contact with one another to form a desiccated low MVTR pressure sensitive tape 10. The desiccated low MVTR material 46 may be butyl. This intimate contact occurs while the desiccated low MVTR material 46 is at an elevated temperature during the extrusion process and, as such, there is excellent bonding between the desiccated low MVTR material 46 and the primer 14. Material 46 is extruded at a slightly smaller width than release layer 16 as shown in FIG. 1. Tape 10 is then cooled at 48 and wound for later use at 50. When the low MVTR pressure sensitive tape 10 is removed from the release layer 16, the primer 14 is carried on an exterior side of the material 46 such that the primer 14 may be placed in contact with the fluoropolymer top sheet 22 to secure bonding between the tape 10 and the top sheet 22. The steps of FIGS. 3 and 4 may be combined into one integrated manufacturing line.

An alternative method to connect the primer to the sealing body is to extrude the sealing body 12 and then coat the primer on the top of the sealing body 12. Drawbacks with this method are that the solvent of the primer contacts the sealing body and degrades the sealing body such as by softening the sealing body or by degrading the sealing body and, when the solvent is water-based, consuming desiccant. Another drawback is that winding the assembly before solvent is gone causes solvent to permeate the package of tape.

Another desirable alternative method is shown in FIG. 5 wherein sealing body 12 is already connected to the bottom sheet of photovoltaic unit 20 before primer and release layer assembly 42 are connected to the exposed face of body 12.

When the final photovoltaic is laminated, the top sheet 22 is adhered to the desiccated low MVTR pressure sensitive adhesive tape 10 such that when it is peeled apart the desiccated low MVTR PSA tape 10 will tear and leave a residue of material 46 on the fluoropolymer top sheet 22 in cohesive failure. This is opposed to a system that does not have the primer film applied to the desiccated low MVTR PSA tape which when peeled from the fluoropolymer top sheet will leave no residue on the substrate.

The MVTR is tested as described in ASTM F1249 which is incorporated herein by reference and a low MVTR is considered to be less than 1 gram per square meter per day for a 60 mil thick test sample when tested at 100% relative humidity at 37.5 degrees C.

Although isobutylene based polymers such as polyisobutylene and butyl rubber are preferred for sealing body 12 due to their low MVTR, other polymers may be used instead of or in addition to isobutylene based polymers. Isobutylene-based polymers will be defined as polymers comprising at least 80 mole percent repeat units from isobutylene. Examples of other polymers include ethylene-propylene polymer, ethylene-propylene diene polymer (EPDM), ethylene-vinyl acetate, acrylic rubber, neoprene rubber, chlorosulfonated polyethylene, urethane, epoxy, natural rubber, polymer from conjugated dienes such as synthetic polyisoprene polybutadiene, nitrile rubber, or styrene-butadiene rubber, and amorphous polyolefins (e.g., homopolymer or copolymer of propene along with other monoolefins or diolefins having from 2 to 10 carbon atoms and having less than 20 wt. % crystallinity as polymers and being other than EPDM and ethylene-propylene polymer). Polyisobutylenes desirably have a number average molecular weight of about 2,000 to 1,400,000 or more, and more desirably from 10,000 to 800,000. The polyisobutylenes are desirably polymers of essentially isobutylene with initiator fragments and/or chain transfer or chain terminator fragments. Butyl rubber is a polymer comprising from about 80 to about 98 or 99 wt. % isobutylene and from about 1 to about 20 wt. % of other monomers such as dienes with from 4 to 12 carbon atoms (e.g., isoprene), and/or aromatic vinyl monomers with from 8 to 16 carbon atoms such as styrene, para-methylstyrene, etc. If para-methylstyrene is a comonomer, desirably the polymer is halogenated (e.g., brominated). Butyl rubber desirably has a number average molecular weight from about 250,000 to about 600,000, more desirably from about 350,000 to about 450,000. The other polymers desirably have number average molecular weights from about 10,000 to 1,000,000 or 2,000,000. Amorphous polyalphaolefins desirably have a number average molecular weight from about 10,000 to about 40,000, more desirably from about 10,000 to about 25,000. If butyl rubber is present in the core, it is desirably from about 5 to about 70 wt. % of the polymers of the core. Amorphous polyalphaolefins are often used in combination with polyisobutylene and/or butyl rubber. The weight ratio of amorphous polyalphaolefins to polyisobutylene and/or butyl rubber is desirably from 1:8 to 8:1 and more desirably from 1:4 to 4:1.

In the foregoing description, certain terms have been used for brevity, clearness, and understanding. No unnecessary limitations are to be implied therefrom beyond the requirement of the prior art because such terms are used for descriptive purposes and are intended to be broadly construed. Moreover, the description and illustration of the invention is an example and the invention is not limited to the exact details shown or described. Throughout the description and claims of this specification the words “comprise” and “include” as well as variations of those words, such as “comprises,” “includes,” “comprising,” and “including” are not intended to exclude additives, components, integers, or steps.

1. An edge sealing tape for photovoltaic modules comprising a sealing body and a primer disposed between a release layer and the sealing body; the primer suitable for bonding the edge sealing tape to a fluoropolymer-based top sheet.

2. The edge sealing tape of claim 1 wherein the sealing body comprises a desiccated polyisobutylene-based material.

3. A photovoltaic module comprising a top sheet and a bottom sheet sandwiching a semiconductor; an edge sealing tape disposed between the top and bottom sheets; the edge sealing tape including a desiccated sealing body and a primer disposed between the top sheet and the sealing body; the top sheet made from a fluoropolymer material.

4. A method for forming the edge sealing tape for photovoltaic modules; the method including the steps of:
applying a primer adapted to bond to a fluoropolymer-based material onto a release layer to define a primer film assembly; the primer having a solvent;
flashing off the primer's solvent from the assembly;
slitting the primer film assembly to define a primed release layer;
extruding a desiccated sealing body material onto the primer of the primed release layer to define a desiccated edge sealing tape; and
winding the desiccated edge sealing tape for storage.

5. The method of claim 4, further comprising the step of winding the primed release layer for storage after the step of slitting the primer film.

6. A method of forming a sealed photovoltaic module comprising the steps of:
sandwiching a photovoltaic semiconductor between a bottom substrate and a top sheet wherein the top sheet is formed from a fluoropolymer-based material;
sealing the edge of the bottom substrate to the edge of the top sheet with a desiccated sealing tape having a sealing body and a primer wherein the primer is adhered to the top sheet and the sealing body is adhered to the bottom substrate is such a way that the sealing body cohesively fails when the top sheet is pulled away from the bottom substrate.

7. The method of claim 6, wherein the sealing body is connected to the bottom substrate before the primer is connected to the sealing body.

8. The method of claim 6, wherein the sealing body is connected to the primer before the sealing body is connected to the bottom substrate.
